(19) United States
(12) Patent Application Publication
(10) Pub. No.: US 2017/0294900 A1
(43) Pub. Date: Oct. 12, 2017

(54) Method for the automated manufacture of an electronic circuit suitable for detecting or masking faults by temporal redundancy, and associated computer program and electronic circuit

(71) Applicants: INRIA INSTITUT NATIONAL DE RECHERCHE EN INFORMATIQUE ET EN AUTOMATIQUE, LE CHESNAY (FR); UNIVERSITE JOSEPH FOURIER, SAINT MARTIN D'HERES (FR)

(72) Inventors: PASCAL FRADET, GRENOBLE (FR); DMITRY BURLYAEV, GRENOBLE (FR); ALAIN GIRAULT, BIVIERS (FR)

(73) Assignees: INRIA INSTITUT NATIONAL DE RECHERCHE EN INFORMATIQUE ET EN AUTOMATIQUE, LE CHESNAY (FR); UNIVERSITE JOSEPH FOURIER, SAINT MARTIN D'HERES (FR)

(21) Appl. No.: 15/321,568

(22) PCT Filed: Jun. 24, 2015
(86) PCT No.: PCT/FR2015/051698

§ 371 Date: Jun. 19, 2017

(30) Foreign Application Priority Data
Jun. 27, 2014 (FR) 1456080

(51) Int. Cl. H03K 3/037; G06F 17/50

(52) U.S. Cl. CPC H03K 3/0375; G06F 17/505; G06F 11/183

(57) ABSTRACT

The method for automated manufacturing of an electronic circuit tolerant to faults by temporal redundancy of maximum order N, comprising a step implemented by computer, according to which every memory cell of the circuit is replaced by a memory block (40) comprising a chain of memory cells in series, and a selection block which, in a temporal redundancy mode of order n1, n1∈[1,N], selects as output data of the memory block the majority content of n1 cells of the block, and can furthermore deliver a fault signal if the contents of the n1 cells differ. Said method is characterized in that the inserted memory blocks allow a dynamic switching from a temporal redundancy mode of order n1 to any other mode of order n2. Said method for N=2, in association with a mechanism for recording with roll-back, allows an error with only a double redundancy instead of a triple redundancy.

The present invention relates to the field of digital electronic circuits adapted to detect or mask faults.

In electronic circuits, various techniques exist allowing soft errors to be detected or masked that are caused by radio or electromagnetic activities of the ‘Single Event Upset’ (SEU) or ‘Single Event Transient’ (SET) type.

A first technique is Triple Modular Redundancy or TMR, in which the hardware elements of an electronic circuit are tripled, the same input data is supplied in parallel to each of the tripled components, and voting modules associated with these tripled components select as the result supplied by the triplet of components the common result supplied in parallel by at least two of the components. This first technique however requires a large number of components, which is a significant drawback, notably in terms of compactness of the electronic circuits.

A second technique is that of temporal redundancy, typically triple temporal redundancy (TTR), according to which the same input data values are supplied three times successively to the same hardware component which delivers three results, and voting modules associated with the component select as result supplied by the component the result supplied at least twice by the component from amongst the three results.

The present invention relates more particularly to this second technique, and notably to a method for the automated synthesis of an electronic circuit adapted to detect or mask faults by temporal redundancy, said method comprising a step implemented by computer, according to which, in order to implement a memory cell function for the electronic circuit, a memory block is inserted into the electronic circuit which comprises a delay chain comprising N memory cells in series, N≧2, and a selection block (voter/detector) which, in one mode of operation corresponding to a temporal redundancy of order n1, involving n1 re-executions, n1∈[1,N], compares the current content of the n1 memory cells storing n1 redundant input data values successively supplied to the memory block, and
if n1>2, select as output data of the memory cell function the majority content of the n1 memory cells and furthermore optionally deliver a fault signal if the contents of two memory cells differ;
if n1=2, deliver as output data of the memory cell function the content of one of the two memory cells containing the current redundant data value and furthermore deliver a fault signal if the contents of these two memory cells differ;
if n1=1, deliver as output data of the memory cell function the content of the given memory cell.
   If n1>2, the circuit masks

$$E [ \frac{n 1 - 1}{2} ]$$

faults and optionally detects

$$E [ \frac{n 1}{2} ]$$

faults, where E is the “integer part” function. If n2=1, deliver as output data of the memory cell function the content of the given memory cell.

The document U.S. Pat. No. 7,200,822 B1 is one example of circuits with triple and higher temporal redundancy. The technique described here however reduces the processing data rate of the circuit.

Accordingly, according to a first aspect, the invention provides a method for automated synthesis of an electronic circuit adapted to detect or mask faults by temporal redundancy of the aforementioned type, characterized in that a control block of the circuit adapted to generate signals for controlling the memory blocks is furthermore inserted, and in that the memory block inserted is adapted to switch, as a function of a switching control signal received from the control block, between said mode of operation corresponding to a temporal redundancy of order n1 and another mode of operation corresponding to a temporal redundancy of order n2∈[1,N] according to which the circuit performs n2 re-executions, n2≠n1, in which the selection block compares the current content of n2 cells determined from amongst the N memory cells storing n2 redundant input data values successively supplied to the memory block, and:
if n2>2, select as output data of the memory cell function, the majority content of said n2 memory cells;
if n2=2, deliver as output data of the memory cell function the content of one of the two memory cells and deliver a fault signal if the contents of the two memory cells differ;
if n2=1, deliver as output data of the memory cell function the content of the given memory cell.

The invention allows the compromise between the corrections/detections of faults and the output data rate of the circuit to be dynamically adapted.

Such a dynamic temporal redundancy allows the number of re-executions to be changed in the course of execution. When this number is equal to 1, the circuit operates without re-execution and with no extra cost.

The dynamic adaptation of the level of temporal redundancy implemented according to the invention notably allows the operation of the circuit manufactured according to the invention to be adapted to the fluctuations of the various types of radiation in the environment of the circuit.

Such a dynamic temporal redundancy notably allows circuits masking an error to be obtained using means equivalent to a double instead of triple temporal redundancy. The principle is to take advantage of the K clock cycles following the occurrence of a fault during which it is assumed that no fault will occur. In a circuit according to the invention, following the detection of an error in a double redundancy mode, the circuit switches into a non-redundant mode in order to carry out a third execution of the erroneous calculation, without the data rate observed at the output of the circuit changing (see the section “Combination of double dynamic temporal redundancy and recording with roll-back” hereinafter).

In various embodiments, the method for automated synthesis of an electronic circuit tolerant to faults by temporal redundancy according to the invention furthermore comprises one or more of the following features:
the memory block inserted furthermore comprises, when N>2, an additional delay block disposed at the output of the delay chain and comprising at least

$$E [ \frac{N - 1}{2} ]$$

memory cells; in a mode of operation corresponding to a temporal redundancy of order n, n>2, every n cycles, the selection block selects as output data of the memory cell function the majority content of the n memory cells of the delay chain, and each i^{th} cycle following said n cycles, with 1i<n, selects as output data of the memory cell function the majority content of a set of last cells of the delay chain and of cells of the additional delay block, said cells of the set storing redundant input data values having been successively supplied to the memory block; this set comprises, for example at said i^{th} cycle, the (n−i) last cells of the delay chain and i cells of the additional delay block;
N=3, n1=1, n1=2, or n1=3 and n2, n2≠n1, takes a value equal to 1, 2 or 3 depending on the switching command; this embodiment corresponds to a triple dynamic redundancy, which therefore includes the modes of operation of order n=1, n=2 and n=3, together with all the possible transitions between these three modes of operation;
N=2, n1=1 or n1=2 and n2, n2≠n1, takes a value equal to 1 or 2 depending on the switching command; this embodiment corresponds to a double dynamic redundancy, which therefore includes the modes of operation of order n=1 and n=2, together with all the possible transitions between these two modes of operation;
the command for switching from the mode of operation according to a temporal redundancy of order 2 to the mode of operation according to a temporal redundancy of order 1, and vice versa, is triggered following the receipt by the control block of a fault signal delivered by one of the memory blocks;
the second cell of the delay chain stores, at each clock cycle of the circuit, the content stored at the preceding clock cycle in the first cell of the delay chain; the inserted memory block furthermore comprises a recording chain adapted, upon receiving a recording command signal from the control block, to store the value of the input signal of the memory block also supplied in parallel to the first cell of the delay chain, and in a mode of operation according to a redundancy of order 2, the recording command signal is generated every other cycle in such a manner that, when redundant data values stored in the two memory cells of the delay chain are compared by the selection block, the last cell of the recording chain comprises in memory the data that was stored two cycles beforehand in each of the two memory cells of the delay chain;
when the control block has received a fault signal delivered by a memory block indicating that redundant data values stored in the two memory cells of the delay chain differ, the control block supplies a roll-back command to the memory block, following which the memory block delivers, as output data of the memory cell function, the current content of the last cell of the recording chain; this embodiment allows an error to be masked with only a double redundancy instead of a triple one;
an input block of the circuit receiving the current external data to be processed oversampled twice is furthermore inserted at the input of the electronic circuit, the input block, in the mode of operation according to a temporal redundancy of order 2, storing the received current external data and furthermore simultaneously supplying to the circuit said received current external data, and the input block, in the mode of operation according to a temporal redundancy of order 1, supplying to the circuit successive non-redundant external data previously stored by the input block in order to allow a third execution of this data by the circuit; and
   according to which an output block of the circuit receiving the data delivered by the circuit is furthermore inserted at the output of the electronic circuit, said output block, in the mode of operation according to a temporal redundancy of order 2, storing the data delivered by the circuit and applying a given delay prior to delivering it, and the output block, in the mode of operation according to a temporal redundancy of order 1, delivering the data delivered by the circuit with no delay, duplicating data delivered by the circuit and delivering the duplicated data,
   the recovery of faults by the circuit thus being masked vis-a-vis the upstream of the circuit and the downstream of the circuit by said input and output blocks. In a mode with no temporal redundancy (n2=1), the input and output blocks allow the roll-back and re-calculation step to be rendered transparent vis-a-vis the external environment.

According to a second aspect, the present invention provides a computer program to be installed in a tool for automated manufacturing of an electronic circuit adapted to detect or mask faults by temporal redundancy, said program comprising instructions for implementing the steps of a method according to the first aspect of the invention during an execution of the program by processing means of the automated electronic circuit manufacturing tool.

According to a third aspect, the present invention provides an electronic circuit adapted to detect or mask faults by temporal redundancy, comprising a set of memory block(s), each memory block of said set comprising a delay chain comprising N memory cells in series, N≧2, and a selection block which, in a mode of operation corresponding to a temporal redundancy of order n1, n1∈[1,N], compares the current content of n1 of said N memory cells storing n1 redundant input data values successively supplied to the memory block, and
if n1>2, selects as output data of the memory cell function the majority content of the n1 memory cells and, optionally, furthermore delivers a fault signal if the contents of two memory cells differ;
if n1=2, delivers as output data of the memory cell function the content of one of the two memory cells and furthermore delivers a fault signal if the contents of the two memory cells differ;
if n1=1, delivers as output data of the memory cell function the content of the given memory cell;

said electronic circuit being characterized in that it comprises a control block of the circuit adapted for generating control signals for said memory blocks, and in that each of said memory blocks is adapted for, depending on a switching control signal received from the control block, switching between said mode of operation corresponding to a temporal redundancy of order n1 and another mode of operation corresponding to a temporal redundancy of order n2∈[1,N], n2≠n1, in which the selection block compares the current content of n2 cells determined from amongst said N memory cells, storing n2 redundant input data values successively supplied to the memory block, and:
if n2>2, selects as output data of the memory cell function the majority content of said n2 memory cells;
if n2=2, delivers as output data of the memory cell function the content of one of the two memory cells and delivers a fault signal if the contents of the two memory cells differ;
if n2=1, delivers as output data of the memory cell function the content of the given memory cell.

These features and advantages of the invention will become apparent upon reading the description that follows, given solely by way of example, and presented with reference to the appended drawings, in which:

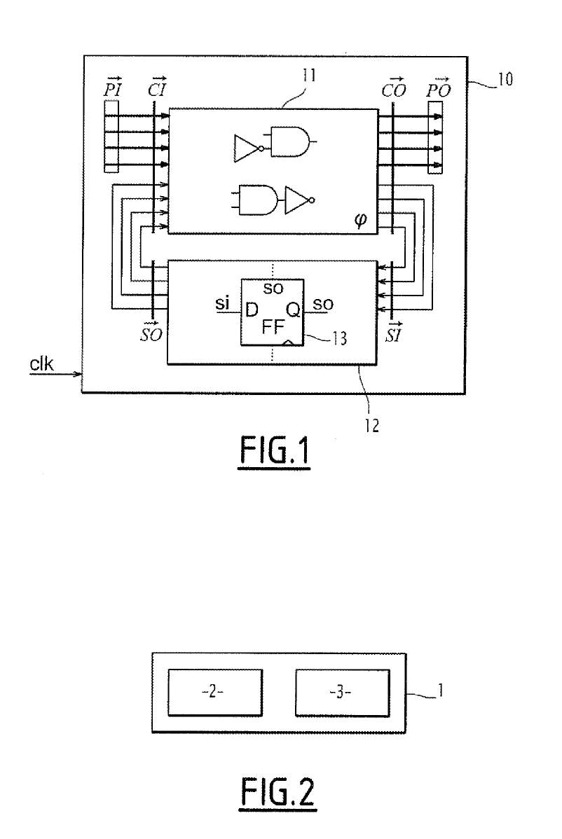

FIG. 1 is a representation of a digital circuit before transformation according to the invention;

FIG. 2 is a view of a tool for automated synthesis of electronic circuits tolerant to faults in one embodiment of the invention;

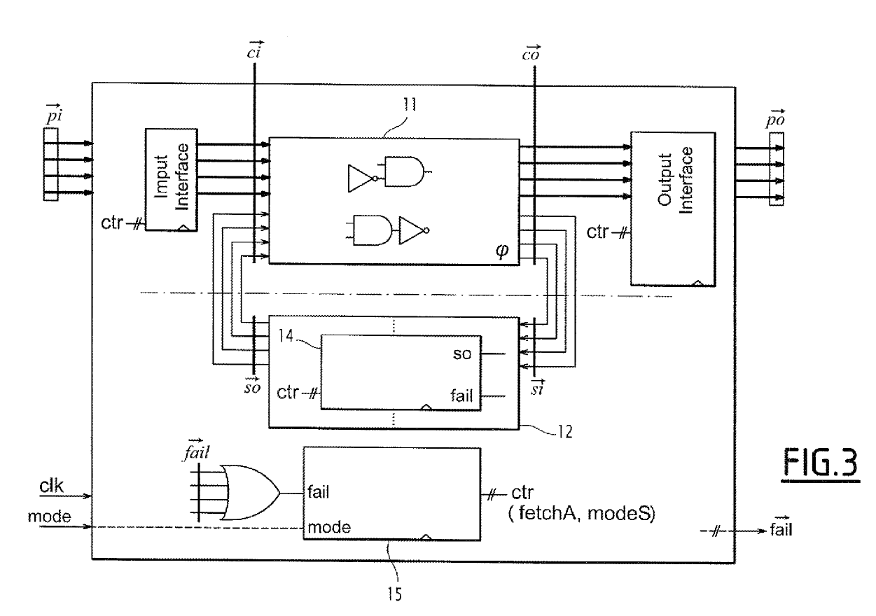

FIG. 3 is a view of a digital circuit after transformation in one embodiment of the invention;

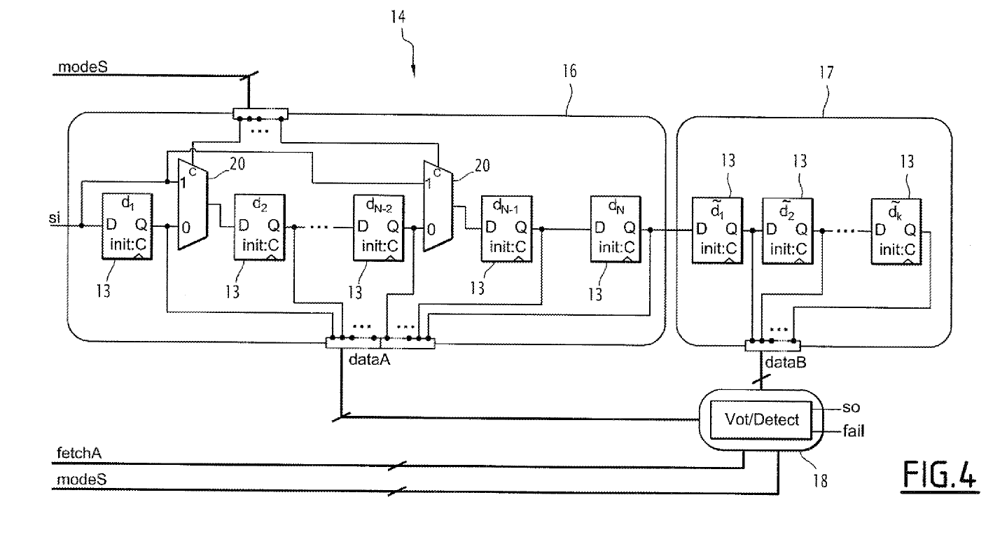

FIG. 4 is a view of a memory block from FIG. 3 in one embodiment of the invention;

FIG. 5 is a view of the memory block from FIG. 3 in one embodiment of the invention corresponding to a double dynamic temporal redundancy;

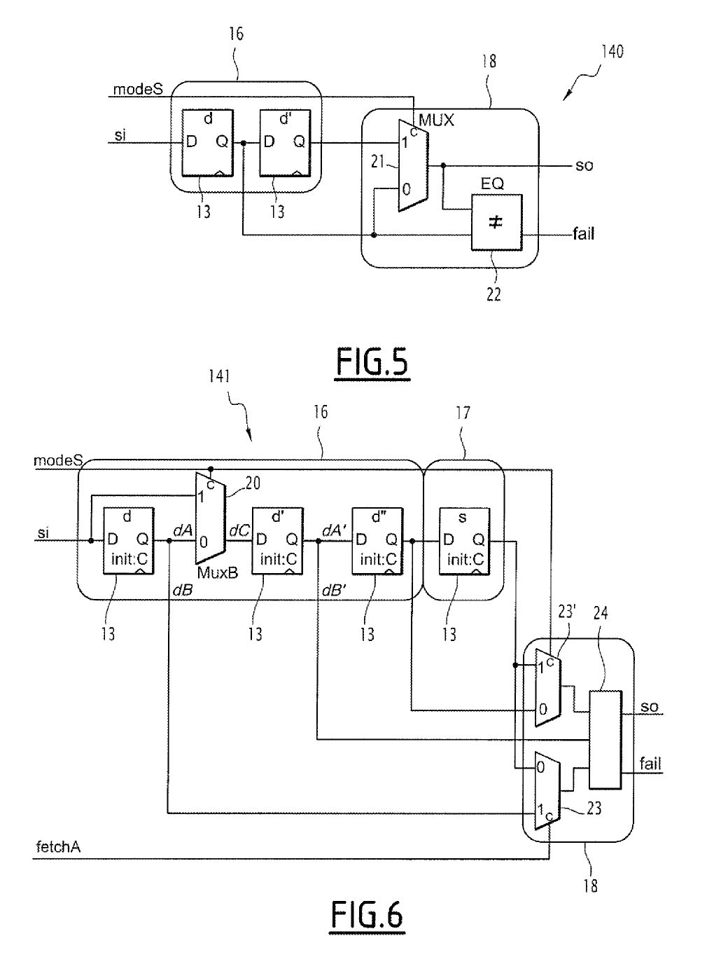

FIG. 6 is a view of the memory block from FIG. 3 in one embodiment of the invention corresponding to a triple dynamic temporal redundancy;

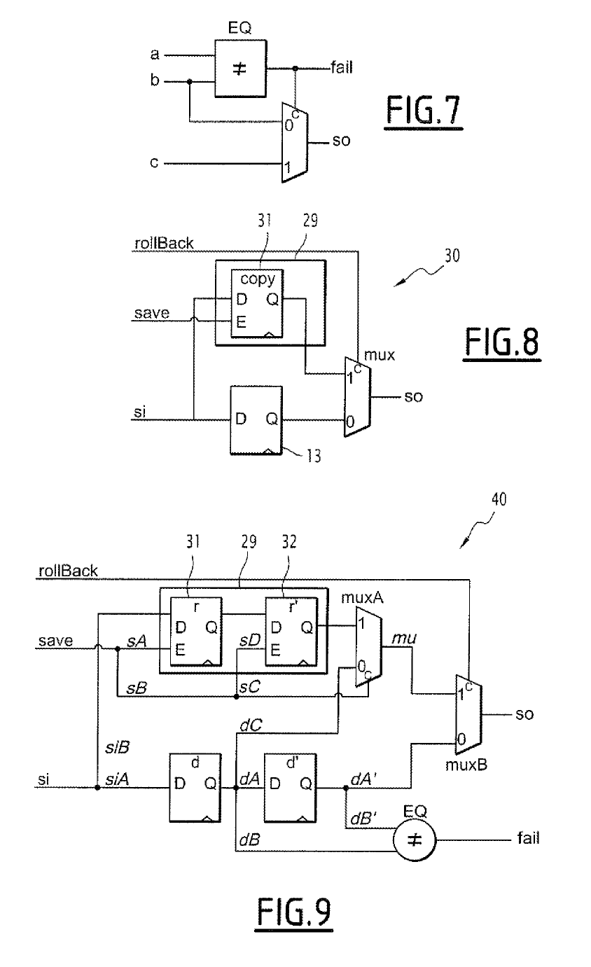

FIG. 7 shows one example of a voter used in FIG. 6;

FIG. 8 is a view of a memory block from FIG. 3 disposing of a recording/roll-back mechanism in one embodiment of the invention;

FIG. 9 is a view of a memory block from FIG. 3 in one embodiment of the invention combining the functionalities of double dynamic temporal redundancy and of a recording/roll-back mechanism;

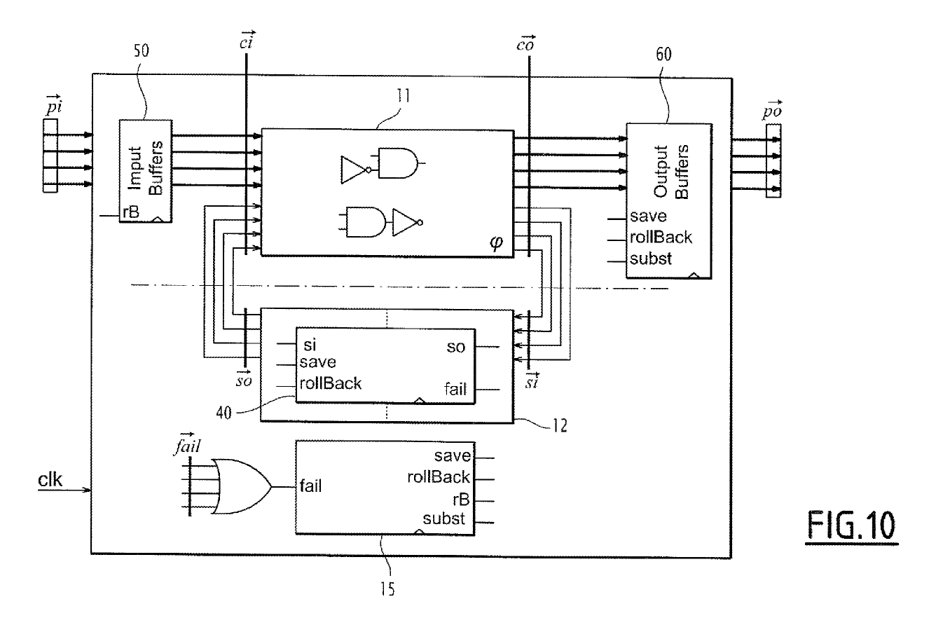

FIG. 10 is a view of a digital circuit in one embodiment of the invention corresponding to a double temporal redundancy with roll-back;

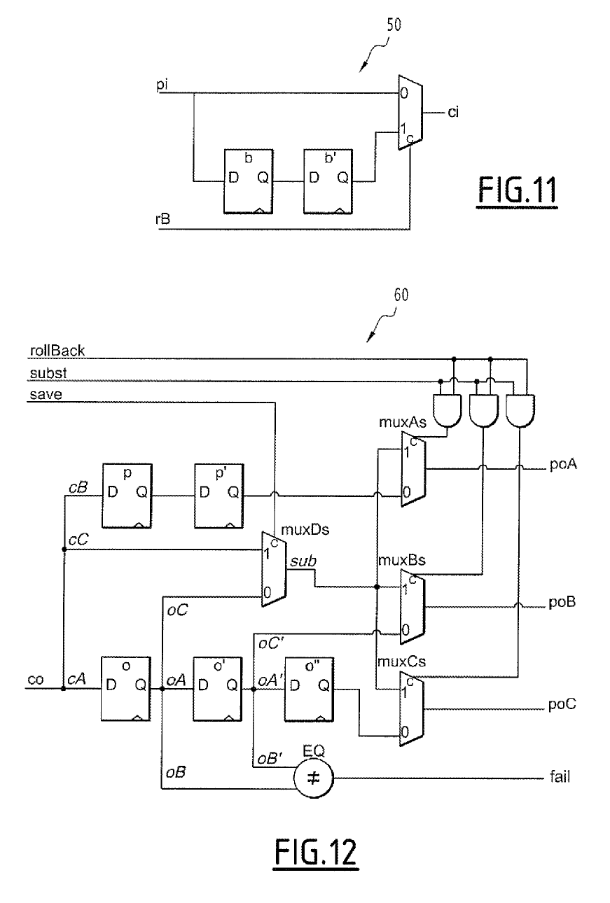

FIG. 11 shows an input buffer memory in one embodiment of the invention having double dynamic redundancy with roll-back;

FIG. 12 shows an output buffer memory in one embodiment of the invention having double dynamic redundancy with roll-back;

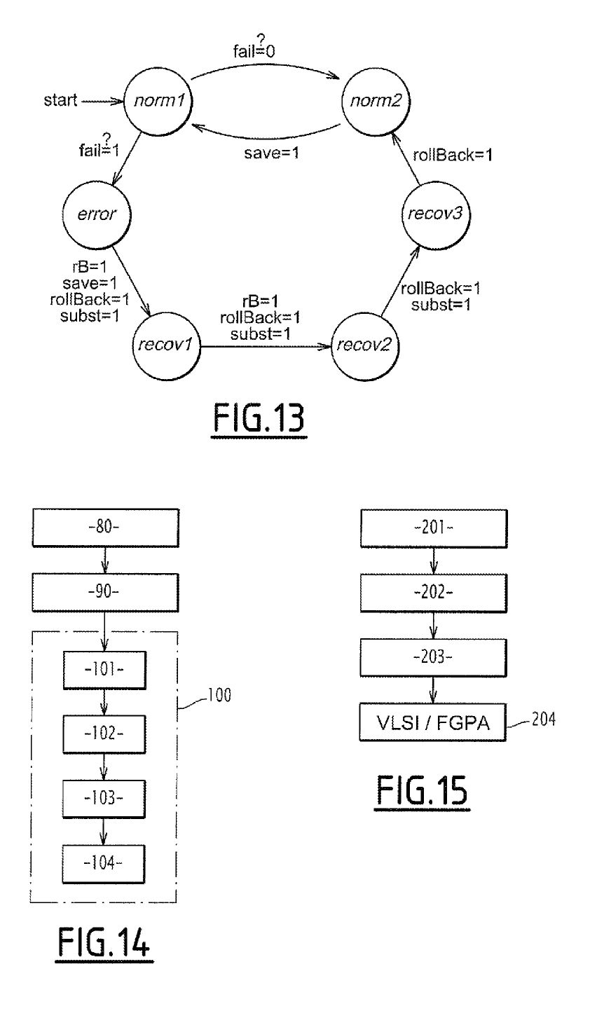

FIG. 13 is a view of a finite state machine of a control block in one embodiment of the invention having double dynamic redundancy with roll-back;

FIG. 14 shows steps of a method in one embodiment of the invention;

FIG. 15 describes steps of a design flow for integrated circuits in one embodiment of the invention.

In the figures, identical references identify similar elements.

FIG. 1 is a general representation of a digital circuit 10, comprising a combinatorial part 11 and a sequential part 12, controlled by a cycle signal clk.

The combinatorial part 11, comprising combinatorial gates AND, OR, NOT etc., performs a Boolean function without a memory φ.

The sequential part 12 comprises memory cells or flip-flops (FF) which each store one bit, or flip-flops (FF) adapted to store the data delivered by the combinatorial part 11. A memory cell 13 is shown in FIG. 1. It receives, on an input wire D, a signal si and delivers, on an output wire Q, an output signal so (it will be noted here that a flip-flop of the D type is described, but the invention is of course applicable to any type of memory cell).

The digital circuit 10 receives at its input a primary input bit-vector \vec{PI} and delivers, at each clock cycle, a primary output bit-vector \vec{PO} at its output.

\vec{CI} and \vec{CO} denote the input bit-vector and the output bit-vector, respectively, of the combinatorial part 11. \vec{SI} and \vec{SO} denote the input bit-vector and the output bit-vector, respectively, of the sequential part 12.

These vectors satisfy the following equalities:

\vec{CO}=φ(\vec{CI}) \vec{CI}=\vec{PI}⊕\vec{SO}\vec{CO}=\vec{PO}⊕\vec{SI} (1)

where ⊕ is the vector concatenation operation.

\vec{ν}ᵢ denotes the value of the bit-vector \vec{v} at the i^{th} clock cycle in the circuit. v denotes any given component of the bit-vector \vec{v}.

The fault models considered take the form “at the most m single event transients (SET) every K clock cycles”, denoted SET(m,K). This encompasses the direct SEUs of a memory cell and the consequent SEUs of an SET in the combinatorial part. According to the fault model SET(1,K), there is no fault occurrence within the K clock cycles following the last fault occurrence.

A SET in the combinatorial part 11 of a circuit may lead to the non-deterministic corruption of any of the memory cells connected (via a purely combinatorial path) to the place where the SET occurred. A SET in the combinatorial part 11 at a cycle i may cause the corruption of output(s) in \vec{PO}ᵢ and of input(s) in \vec{SI}ᵢ, which then cause the corruption of memory cells in the sequential part 12. This latest corruption is visible at the clock cycle i+1. A SET may occur on any of the wires of the circuit (connections between logic gates, memory cells, inputs, outputs).

FIG. 2 shows a tool 1 for automated synthesis of electronic circuits tolerant to faults in one embodiment of the invention. This tool 1 comprises a microprocessor 2 and a memory 3. In the memory 3, a program of software instructions P is stored which, when it is executed by the microprocessor 2, is adapted to implement the steps indicated hereinbelow for automatic transformation of the design of the circuit.

Based on a description of a digital circuit of the type with a network of logic gates (or ‘netlist’) comprising AND, OR, NOT gates and memory cells or flip-flops, such a tool 1 is adapted to carry out a step for automatic transformation of the design of the circuit in order to obtain a transformed circuit, then to fabricate an FGPA circuit or an ASIC circuit using the transformed circuit in the form of a netlist.

The vectors in lower-case letters, for example \vec{pi}, \vec{po}, represent the signals in a digital circuit transformed by the digital circuit manufacturing tool which correspond to the vectors in upper-case letters, for example \vec{PI}, \vec{PO}. They satisfy the same equalities (1) previously indicated.

Dynamic Temporal Redundancy According to first aspect of the invention, the tool 1 implements a step for automatic transformation 100 of the design of the circuit so as to obtain a circuit with a tolerance to faults by dynamic temporal redundancy.

A circuit such as obtained after transformation is adapted to switch, without process interruption, from a mode of operation according to a temporal redundancy of order n to a mode of operation according to a temporal redundancy of order m, with n≠m, following a mode switching control signal indicating the passage from the order n to the order m, which allows a dynamic compromise between the data rate and the tolerance to faults.

In this transformation step 100, the tool 1 replaces each memory cell 13, with input Si, with output SO and included in the original circuit, by a memory block 14 with input si and with output so, and furthermore adds a control block 15 which generates control signals, as shown by the modules 12 and 15 in FIG. 3.

The memory block 14 implements a dynamic temporal redundancy mechanism adapted to mask and/or detect faults caused by SETs in at least one of the modes of operation of the memory block 14. The memory block 14 is adapted to switch in the course of the operational phase of the circuit, from a mode of operation according to a temporal redundancy of order n to a mode of operation according to a temporal redundancy of order m, with n and m integer numbers and n≠m, following a mode switching command indicating the passage from the order n to the order m. In one embodiment, the control block 15 determines the control signals for the memory block 14 as a function notably of the order n of the temporal redundancy currently selected for the circuit. It is implemented for example by means of a finite state machine, for example itself protected by TMR.

Henceforth, mode n will refer to the mode of operation with temporal redundancy of order n (n a natural integer):
the input stream \vec{PI} of the circuit is over-sampled n times and denoted \vec{pi}, the data rate of the initial circuit being n times higher than the data rate of the transformed circuit;
the memory block 14 is adapted to detect or mask up to

$$E [ \frac{n }{2} ]$$

faults (E[.] represents the “integer part” function) when n is greater than or equal to 2, depending on comparisons between them, every n clock cycles, of the n data values successively stored by the memory block and corresponding to the n redundant input signals si (in the case of a fault masking, the output data selected by the memory block is the majority data from amongst the n data values compared).

A memory block 14 comprises a dynamic delay pipeline, an additional delay line and a voter/detector.

The dynamic delay pipeline is adapted, in a temporal redundancy mode of order n, to store n successive signals supplied to the input of the memory block. It is adapted to dynamically modify its delay function n as a function of control signals transmitted by the control block 15.

The additional delay chain is adapted, in a temporal redundancy mode of order n, to store

$$E [ \frac{n - 1}{2} ]$$

signals having been successively supplied to the input of the memory block 14, in such a manner as to allow the voter/detector 18 to make n successive voting/detection decisions (in other embodiments, the additional delay line is adapted to save more than

$$E [ \frac{n - 1}{2} ]$$

signals having been successively supplied).

The memory block 14 comprises a voter/detector adapted for determining n successive decisions of the masking or/and fault detection type, in a temporal redundancy mode of order n, as a function of data stored in the pipeline and/or in the additional delay line.

A memory block 14 is shown in one embodiment, in FIG. 4. The dynamic delay pipeline 16 comprises N (N≧2) memory cells 13 in a cascade configuration and N−2 multiplexers 20 (it will be noted that other configurations are possible: for example, it would be possible not to use multiplexers 20 and to change the voter/detector so as to select the cells to be compared/voted.

The N successive memory cells are respectively denoted d₁, d₂, . . . , d_{N}.

A multiplexer 20 is disposed between each cell dᵢ and each cell dᵢ₊₁, i∈[1,N−2] (when N>2). The cell d₁ has the signal si as input signal. The cell d_{N} has the output signal from d_{N-1} as input signal. The output from each cell dᵢ, ∈[1,N−2], is delivered to the input 0 of the multiplexer 20 disposed between each cell dᵢ and each cell dᵢ₊₁. The signal si is delivered to the input 1 of the multiplexer 20 disposed between each cell dᵢ and each cell dᵢ₊₁. The output of the multiplexer 20 disposed between the cells dᵢ and dᵢ₊₁, i∈[1,N−2], is delivered to the input of the cell dᵢ₊₁.

In a known manner, a control bus, here denoted modeS, indicates to each multiplexer 20 which of its inputs 0 and 1 is to be delivered at the output of the multiplexer 20 (if the signal from the control bus modeS is equal to 1: the input 1, receiving si, is delivered at the output of the multiplexer; if the signal from the control bus modeS is equal to 0: the input 0, receiving the output from the preceding cell, is delivered at the output of the multiplexer). This known operation of a multiplexer is also that of the other multiplexers described further on and will not therefore be systematically recalled.

The output of the cells dᵢ, i=1 to N, is furthermore supplied to the voter/detector 18 over the databus dataA.

The control signals modeS depend on the temporal redundancy mode selected.

The additional delay line 17 comprises

$$k = E [ \frac{n - 1}{2} ]$$

memory cells \tilde{d}₁, . . . , \tilde{d}ₖ in series. The input of \tilde{d}₁ is supplied by the output of d_{N}. The input of \tilde{d}ⱼ₊₁ is supplied by the output of \tilde{d}ⱼ, with j≧1. The contents of these cells are supplied to the databus dataB.

$$E [ \frac{n - 1}{2} ]$$

of these cells are used by the voter/detector 18 to make the last n−1 decisions relating to n redundant data values at the input of the memory block 14.

The voter/detector 18 is adapted to determine the output signal so as a function of redundant data values present on the bus dataA and dataB and to take decisions for error masking and/or detection according to the current order n of temporal redundancy. In a masking decision, the voter/detector compares the inputs supplied to it and selects as signal so the majority value from amongst these inputs.

If n=1 (mode of operation=mode 1), there is no temporal redundancy. The data rate of the transformed circuit is the same as the data rate of the initial circuit. There is no detection nor correction of faults.

In the embodiment described, the signal si is supplied to the input of the cell by controlling the multiplexers 20 (in other embodiments, for example with no multiplexer 20, it is supplied to each cell). It is the content of the cell d_{N-1} that is delivered as signal so by the voter/detector 18 (thus, the signal so at the cycle i is the signal supplied to the input of the memory block 14 at the cycle i−1).

If n=2 (mode of operation=mode 2), the signal si is supplied to the input of the cell d_{N-1} at an even cycle 2i; at the cycle 2i+1, the redundant signal si is in turn supplied to the input of the cell d_{N-1,} whereas the output of the cell d_{N-1} is supplied to the input of the cell div. The voter/detector 18 supplies as signal so the content of div at each cycle. At the cycle 2i, it compares the data values (coming from redundant input data values) stored in the memory cells d_{N-1} and d_{N} after they have been supplied to the input of the memory block 14 at the cycle 2i−1 and 2i−2, and delivers a signal fail indicating 0 if the data values compared are equal (no fault detected) and indicating 1 if the data values compared are not equal (fault detected). At the odd cycles, the value of the signal fail is ignored because the comparison carried out relates to non-redundant data. The value of this signal fail is for example supplied to the control block 15 or to the output of the circuit.

If n=3 (mode of operation=mode 3), the cells d_{N-2}, d_{N-1} and d_{N} are used, together with \tilde{d}₁, in a similar manner to the respective cells d, d′ , d″ and s in FIG. 6 the operation of which is described hereinbelow.

Generally speaking, in a temporal redundancy mode of order n≧3 (mode of operation=mode n), the cells of the pipeline d_{N-n+1}, . . . , d_{N-1} and d_{N are} used, together with the cells of the additional delay line \tilde{d}₁, . . . ,

$${\tilde{d}}_{E [ \frac{n - 1}{2} ]} .$$

If n is the order of the mode of redundancy currently selected for the operation of the circuit, the same input data values are supplied n times to the combinatorial part 11 of the circuit which re-calculates n times the same result, which is then progressively saved in the n memory cells d₁, d₂, . . . , dₙ of the pipeline 16. These n redundant results constitute the current set of redundant results

When these n redundant results are stored in the n cells d₁, d₂, . . . , dₙ, the voter/detector 18 takes a first decision as a function of these n results supplied to it at the input on the bus dataA. Then, the redundant data values at the output of the cell d_{N} are successively stored in the additional delay line 17, which will contain up to

$$E [ \frac{n - 1}{2} ]$$

of them in the n−1 following cycles during which the decider/voter takes n−1 decisions on the redundant results of the current set stored in the memory cells of the pipeline 16 and of the additional delay line 17, via the databus dataA and dataB. Thus, at the next i^{th} (i<n) cycle, the decision relates to the majority value from amongst the (n−i) redundant results of the current set of redundant results in the cells d_{Nn-1+i}, . . . , d_{N} and the first min(i,

$$E [ \frac{n - 1}{2} ] )$$

cells of the additional delay line 17 also storing this redundant result (i.e. \tilde{d}₁, . . . ,

$${\tilde{d}}_{min ( l , E [ \frac{n - 1}{2} ] )} .$$

Thus, at the next (n−1)^{th} cycle, the decision only relates to the redundant result of the current set of redundant results in the cell dₙ and to the redundant results of the current set of redundant results in the

$$E [ \frac{n - 1}{2} ]$$

cells of the additional delay line 17 in question. Then, in the pipeline 16, the n−1 redundant results of the following set of redundant results are contained in the cells d_{N-n+1} and d_{N-1}.

The control signals fetchA indicate, at each clock cycle, depending on the order of temporal redundancy currently selected, which of the outputs of the memory cells on the bus dataA, dataB that the voter/decider 18 must consider in its current decision.

By way of illustration of one embodiment of the invention, a circuit is produced with alternative modes of operation 2 and 5, which thus either detects a single SET (mode 2), or masks up to two SETs (mode 5).

The control signals modeS, fetchA are determined by the control block 15, depending notably on the temporal redundancy mode selected and on the current cycle. A change of temporal mode is carried out, depending on the embodiments, in an automated manner or otherwise, for example when a radiation threshold has been exceeded within the environment of the circuit or following the occurrence of a fault.

During changes of modes, the modules interfaced with the circuit must adapt to the changes of order of redundancy; notably the level of over-sampling has to follow the order of redundancy.

The cases of N=2 and N=3 are detailed hereinafter.

Dual Dynamic Temporal Redundancy

In one embodiment of the invention presently being considered, the value of N is chosen equal to 2, the circuit manufactured according to the invention thus disposing of a double dynamic temporal redundancy mechanism according to the principle presented hereinabove according to which the operation of the circuit can switch between the temporal redundancy modes of order n=1 and n=2.

The transformation 100 therefore comprises the means for implementing double over-sampling of the input stream \vec{PI}, which are enabled when n=2, the substitution of each memory cell included in the original circuit by a memory block 140 and the addition of a control block 15.

In this circuit, with reference to FIG. 5, the memory block 140 replacing each memory cell included in the original circuit comprises a pipeline 16 comprising the cells d and d′, respectively corresponding to the cells d_{N-1}, d_{N} in FIG. 4 and a voter/detector 18.

The voter/detector 18 comprises a multiplexer 21 and a comparator 22.

The multiplexer 21 comprises two inputs 0 and 1. The output signal so of the memory block is the output signal of the multiplexer. It is equal either to the input 1 or to the input 0 depending on the control signals modeS. The signal si is supplied to the input of the cell d, the output of the cell d is supplied to the input of the cell d′, to the input of the comparator 22 and to the input 0 of the multiplexer 21. The output of the cell d′ is supplied to the input 1 of the multiplexer 21.

The comparator 22 is intended to compare the values supplied at each clock cycle to its two inputs, and to deliver a signal fail=0 when the values are equal and a signal fail=1 when the values differ.

n=1 mode

In n=1 mode, \vec{pi}ᵢ=\vec{PI}ᵢ ∀i a non-zero integer. At the cycle i, the bit siᵢ is presented at the input of the cell d. In this mode, the multiplexer 21 is controlled by the signal modeS=0 emitted by the control block 15, in such a manner that the multiplexer 21 output, i.e. the signal so, is always equal to the input 0 of the multiplexer, i.e. to the output of the cell d.

n=2 mode

In n=2 mode, the input stream of the circuit is over-sampled twice: \vec{pi}₂ᵢ₋₁=\vec{pi}₂ᵢ=\vec{PI}ᵢ.

The cells d and d′ therefore contain redundant data values at each even cycle (by convention, the first cycle is numbered 0). For example, si₁=u, si₂=u, then the pair (d, d′) will successively contain the values (0,0), (u,0), (u,u) . . . assuming that the initial values in (d, of) were (0,0).

At each cycle, the voter/detector 18 supplies the content of d′ as signal so. In this mode, the multiplexer 21 is controlled by the signal modeS emitted by the control block 15, in such a manner that its output, i.e. the signal so, is always equal to the input 1 of the multiplexer.

The value of the signal fail returned by the comparator 22 is not significant at odd cycles, since d and d′ do not contain any redundant data values.

At an even cycle 2i, a value of fail signal equal to 1 indicates the detection of an error in the redundancy of the data values then stored in d and d′, i.e. supplied to the input of the memory block 140 at the cycles 2i and 2i−1.

The double dynamic temporal redundancy according to the invention allows, in n=2 mode, errors in the fault model SET(1,K) to be detected for all K≧2 and in n=1 mode, the same data rate as the initial circuit to be obtained.

Triple Dynamic Temporal Redundancy

In another embodiment of the invention now being considered, the value of N is chosen as equal to 3, the circuit manufactured according to the invention thus disposing of a triple dynamic temporal redundancy mechanism according to the general principle presented hereinabove, according to which the operation of the circuit can switch between the temporal redundancy modes of order n=1, n=2 and n=3.

The transformation 100 therefore comprises the implementation of over-sampling means (x n), which are enabled when n=2 or n=3, the substitution of each memory cell included in the original circuit by a memory block 141 and the addition of a control block 15.

In this circuit, with reference to FIG. 6, the memory block 141, replacing each memory cell included in the original circuit, comprises a pipeline 16 comprising the cells d, d′ and d″, respectively corresponding to the cells d_{N-2}, d_{N-1}, d_{N} in FIG. 4, the additional delay line 13 and a voter/detector 18.

A multiplexer 20, comprising two inputs 0 and 1, is disposed upstream of the input of the cell d′. The input of d′ is the output of the multiplexer 20. The multiplexer 20 receives on its input 1 the signal si and on its input 0 the output of the cell d. The control signal modeS indicates which of the inputs 0 or 1 is equal to the output of the multiplexer 20: modeS=0 (n=3), the length of the pipeline 16 is 3: the output of the multiplexer is set equal to the input 0; modeS=1 (n=1 or n=2), the active length of the pipeline 16 is 2: the output of the multiplexer is set equal to the input 1.

The additional delay line 13 comprises a memory cell s corresponding to the cell \tilde{d}₁ shown in FIG. 4.

The voter/detector 18 comprises two multiplexers 23, 23′ and a voter 24.

The voter 24 receives 3 inputs. These 3 inputs are the outputs of d′ and of the multiplexers 23, 23′. The voter 24 compares the three inputs, selects from amongst them the majority input value, this selected value forming the output signal so delivered by the memory block 141. The voter 24 furthermore compares the outputs of d′ and d″ and delivers a signal fail=0 if they are equal and a signal fail=1 in the opposite case.

One example of a structure of such a voter 24 is shown in FIG. 7, where the signal fail is the result of a comparison between a and b, and so is the result of the majority vote carried out on the inputs a, b and c.

n=3 mode

In n=3 mode (redundancy of order 3), in normal operation (i.e., with no fault), the behavior of all the memory blocks is described by the following equations:

∀i a non-zero integer, \vec{si}ᵢ=\vec{d}ᵢ₊₁=\vec{d}′ᵢ₊₂=\vec{d}″ᵢ₊₃=\vec{s}ᵢ₊₄=\vec{so}₁₊₃ (2)

The over-sampled input and output signals of the circuit satisfy the equations (1), namely:

\vec{co}ᵢ=φ(\vec{ci}ᵢ) \vec{ci}ᵢ=\vec{pi}ᵢ⊕\vec{so}ᵢ \vec{co}ᵢ=\vec{po}ᵢ⊕\vec{si}ᵢ (3)

The original input bit stream \vec{PI} is over-sampled 3 times:

\vec{pi}₃ᵢ₋₂=\vec{pi}₃ᵢ₋₁=\vec{pi}₃ᵢ=\vec{PI}ᵢ (4)

The control signal modeS is equal to 0.

Based on the equations (2), (3) and (4), it follows that the output bit stream from the combinatorial part co after the transformation 100 of the circuit is the output stream \vec{CO} of the original circuit over-sampled three times:

\vec{co}₃ᵢ₋₂=\vec{co}₃ᵢ₋₁=\vec{co}₃ᵢ=\vec{CO}ᵢ

In this mode of operation, the three cells d, d′, d″ have an equal content every (3i−2) cycles, i.e.: d₃ᵢ₋₂=d′₃₁₋₂=d″₃ᵢ₋₁.

At each cycle, a vote of the voter/detector 18 selecting the majority value from amongst the contents of the three cells d, d′, d″ thus masks a fault, and only the result of this vote is supplied via so to the combinatorial part of the circuit.

At the first cycle following each specific cycle where the three cells d, d′, d″ have an equal content, the cell s stores the redundant value stored at the specific cycle in d″, then, at the second following cycle, the cell s stores the redundant value stored at the specific cycle in d′, i.e.: s₃ᵢ₋₁=d″₃ᵢ₋₂ and s₃ᵢ=d′₃ᵢ₋₂, which allows the necessary level of redundancy to be kept in the memory block.

The vote at the specific cycle 3i−2 is carried out on the contents of the cells d, d′ and d″ and the vote is instead carried out on the content of the cells d′, d″ and s the two following cycles, selecting the majority value from amongst these three contents. This functionality is implemented by means of the control signal fetchA emitted by the control block 15: fetchA=1 at each cycle 3i−2 (i.e. output of the multiplexer 23 is set equal to the input 1 of the multiplexer 23) and fetchA=0 the cycles 3i−1 and 3i (i.e. output of the multiplexer 23 is set equal to the input 0 of the multiplexer 23).

Assuming that at cycle 3i−2, d, d′ and d″ comprise a correct redundant value a; the vote takes place on (a, a, a) stored in (d, d′, d″); the vote at the cycle 3i−1 will take place on (a, a, a) stored in (d′, d″, s), d then containing the next value of the bit on the initial stream, denoted b; and, at the cycle 3i, the vote takes place on (b, a, a) stored in (d′, d″, s), d and d′ then each containing the value b. Thus, if d″ is corrupted at this cycle 3i, the vote may return an erroneous value which will be propagated to the following block. However, since this erroneous value is preceded by two correct values, it will be corrected at the next cycle in the following block (an additional SET not then being able to occur according to the fault model being considered).

n=2 mode

In n=2 mode (redundancy of order 2), in normal operation (i.e., with no fault), the behavior of all the blocks is described by the following equalities:

∀i a non-zero integer, \vec{si}ᵢ=\vec{d}ᵢ₊₁=\vec{d′}ᵢ₊₂=\vec{d″}ᵢ₊₃=\vec{s}ᵢ₊₄=\vec{so}ᵢ₊₂

In order to set the output of the multiplexer 20 equal to the input 1 of the multiplexer 20, the control signal modeS is therefore set to 1 by the control block 15 in this mode.

The signal fetchA is set equal to 1.

The cell s will not participate in the decisions.

In n=2 mode, the input stream of the circuit is over-sampled twice: \vec{pi}₂ᵢ₋₁=\vec{pi}₂ᵢ=\vec{PI}ᵢ.

The output bit stream from the combinatorial part \vec{co} after the transformation 100 of the circuit is the output stream \vec{CO} of the original circuit over-sampled twice:

\vec{co}₂ᵢ₋₁=\vec{co}₂ᵢ=\vec{CO}ᵢ

The detection properties are based on the following equality: ∀i a non-zero integer, \vec{d′}₂ᵢ₋₁=\vec{d″}₂ᵢ (5).

A new value a on \vec{si} is supplied to d and d′, then at the following cycle, is propagated to d″, whereas a redundant data value equal to a is again supplied on \vec{si} to d and d′.

The detection error is carried out by the voter/detector 18 by comparing d′ and d″ every (2i−1)th cycle, since in the absence of a fault, their content should be equal according to the equation (5). If their content is not equal, a signal fail=1 is generated.

so is the result of the vote (selecting the majority value) on d, d′, d″ at each cycle.

A SET on si can corrupt both d and d′ and the vote will not mask this fault. However, if a SET takes place on one of the three cells d, d′, d″ during an odd cycle, it will be masked by the vote.

n=1 mode

In n=1 mode (no redundancy), in normal operation (i.e. with no fault), the behavior of each memory block is described by the following equations:

∀i a non-zero integer, i\vec{si}ᵢ=\vec{d}₁₊₁=\vec{d′}ᵢ₊₁=\vec{d″}ᵢ₊₂=\vec{s}ᵢ₊₃=\vec{so}ᵢ₊₁ (6)

In order to set the output of the multiplexer 20 equal to the input 1 of the multiplexer 20, the control signal modeS is therefore set to 1 by the control block 15 in this mode.

The signal fetchA is set equal to 1.

In n=1 mode, the input stream of the circuit is not over-sampled: \vec{pi}ᵢ=\vec{PI}ᵢ.

The output bit stream from the combinatorial part co after the transformation 100 of the circuit is the output stream \vec{CO} of the original circuit: \vec{co}ᵢ=\vec{CO}ᵢ. In this mode, the circuit does not possess any fault detection property, nor fault masking.

The corresponding control signals are fetchA=1 and modeS=1.

According to the equation (6), in the absence of a fault, d is equal to d′ at each clock cycle. As a consequence, the vote by the voter/detector 18 returns the value of d (and d′) at each cycle. Formally, \vec{co}ᵢ=\vec{d}ᵢ₊₁=\vec{d′}ᵢ₊₁=\vec{d″}ᵢ₊₂\vec{=ci}ᵢ₊₁. If d and/or d′ are corrupted, then the vote on {d, d, d′} may return an erroneous value (without setting the signal fail to 1); this is why this mode does not mask nor detect faults.

The triple dynamic temporal redundancy according to the invention allows the SETs of the model SET(1,K) to be masked for all K greater than 4 cycles.

Recording Mechanism with Roll-Back

According to another aspect of the invention which can be implemented independently of the dynamic temporal redundancy previously presented, the tool 1 implements a step for automatic transformation 101 of the design of the circuit in order to obtain a circuit equipped with a mechanism for recording the state of the circuit, this recording being triggered by a control signal named save, and furthermore equipped with a mechanism for rolling back the state of the circuit into the state thus recorded, this rolling back being triggered at a later time by a control signal named rollBack.

For this purpose, in a transformation step 101, the tool 1 replaces each memory cell 13 with input si, with output so and included in the original circuit shown in FIG. 1, by a memory block 30 with input si and with output so as shown in FIG. 8, and furthermore adds a control block which generates control signals save and rollBack.

The memory block 30 comprises a memory cell 13 receiving on its input D a signal si, delivering on its output Q a signal to the input 0 of a multiplexer mux. The memory block 30 furthermore comprises a recording block 29 adapted to record the signal si which is supplied to its input when a signal save equal to 1 is addressed to it. The signal si thus recorded by the recording block is supplied to the input 1 of the multiplexer mux.

In the present case, the recording block 29 comprises a memory cell 31, named copy. When a signal save equal to 1 is supplied to it on its input E (enable), the memory cell 31 stores the signal si supplied to it on its input D, in parallel with its feed to the input D of the cell 13. When save is equal to 0, the signal si is not stored in the memory cell copy 31.

The output Q of the cell copy 31 is supplied to the input 1 of the multiplexer mux. The multiplexer mux delivers the signal so on its output. The signal so is equal to the input 0 of the multiplexer when rollBack is equal to 0 and is equal to the input 1 of the multiplexer 31 when rollBack is equal to 1.

Thus, for as long as rollBack is equal to 0, the output so is equal to the content of the cell 13. When rollBack becomes equal to 1, it is the content of the cell copy, corresponding to the last setting to 1 of the signal save, that is supplied at its output so.

The same signal save at 1 supplied at the cycle i to all (or to a sub-set) of the memory blocks 30 of the circuit allows the current state of the cells 13 of the circuit to be recorded in the cells copy 31 at the cycle i. This state remains stored in memory for as long as a new signal save at 1 has not been supplied.

Combination of Double Dynamic Temporal Redundancy and of Recording with Roll Back

In one embodiment of the invention now being considered, the aspects of double dynamic temporal redundancy and of recording with roll-back are combined.

The value of N is chosen equal to 2, and the operation of the circuit can switch between the temporal redundancy modes of order n=1 and n=2.

Such a circuit is adapted to mask errors by using only a temporal redundancy of level 2 instead of a temporal redundancy of level 3.

For this purpose, in a transformation step 102, the tool 1 replaces each memory cell 13, with input si and with output so, included in the original circuit shown in FIG. 1, by a memory block 40, with input si and with output so as shown in FIG. 9, and furthermore adds a control block 15 which generates control signals save and rollBack. A view of the transformed circuit resulting from this transformation is shown in FIG. 10.

Such a transformation involves the implementation of means for double over-sampling of the primary inputs of the circuit, which, in the embodiment being considered, are always enabled independently of the value of the active order of redundancy, the addition of input buffer memories to all the primary inputs PI of the initial circuit, and lastly, the addition of output buffer memories to all the primary outputs PO of the initial circuit.

φ(\vec{ci}) is calculated twice, the results are compared and, if an error is detected, φ(\vec{ci}) is calculated a third time, by virtue of the content of the input buffer memories.

The input stream, over-sampled twice, verifies: \vec{pi}₂ᵢ₋₁=\vec{pi}₂ᵢ=\vec{PI}ᵢ.

The memory block 40 thus comprises the cells d and d′ disposed in series for saving redundant data values. It furthermore comprises a comparator EQ comparing the content of the cells d and d′ with generation of a signal fail indicating the result of the comparison.

The memory block 40 furthermore comprises a recording block 29 adapted to store the signal si which is supplied to its input when the control signal save is set to 1. The output of the recording block is supplied to the input 1 of the multiplexer muxA, whereas the output of the cell d is supplied to the input 0 of the multiplexer muxA. The multiplexer muxA is also controlled by the signal save.

In the embodiment being considered, the recording block 29 comprises the cells r and r′ disposed in series, the signal si is supplied to the input D of the cell r, the output Q of the cell r is supplied to the input D of the cell r′, and the output Q of the cell r′ is the output of the recording block 29. The storing by the cells r and r′ of the signal supplied to them on their input D only takes place when the control signal save supplied on their input E is set to 1.

A multiplexer muxB receives the output mu from the multiplexer muxA on its input 1 and receives, on its input 0, the output of the cell d′. The multiplexer muxB is controlled by the control signal rollback. When rollBack=0 (similar to the modeS=1 case in double dynamic redundancy), the output so of the multiplexer muxB is equal to its input 0, and when rollBack=1, the output so of the multiplexer muxB is equal to its input 1.

When the control signal rollback=0 (similar to the modeS=1 case in double dynamic redundancy), the mode of operation is a temporal redundancy of order 2 and the output of the memory block so is equal to the content of the cell d′.

When the control signal rollback=1 (which is equivalent to the modeS=0 signal), the mode of operation has no temporal redundancy (i.e. of order 1). The output of the memory block so is equal to the content of the cell d when save is equal to 0 and the output of the memory block so is equal to the output of the recording block, i.e. in the embodiment being considered to the content of the cell r′ when save is equal to 1.

The recording block 29 allows the value of si to be stored during 4 clock cycles and allows the circuit to re-position itself onto this stored value in the case of a detection error.

As indicated hereinabove, an input buffer memory 50 is furthermore inserted after each primary input P1 of the original circuit in order to store the last two bits of the input stream (each input corresponds to a component of the vector \vec{pi}). This input buffer memory 50, shown in FIG. 11 in one embodiment, is implemented by a pipeline of two memory cells b and b′, where pi denotes the primary input of the original circuit. The control signal rB is set to 1 by the control block during the recovery phase, after a detection error made by the comparator EQ during an odd cycle. The content of the cells b and b′ is only used during the recovery phase for re-executing the last two cycles. These bits are supplied to the combinatorial part 11 of the circuit instead of the bits of the input stream. The cells b and b′ are also used to store the inputs that are supplied during these two cycles. During the recovery phase, the vector \vec{ci} thus comprises the vector \vec{pi} which comes from the input buffer memories and the vector \vec{so} coming from the re-positioned memory blocks. If the error is detected at the cycle i, then the roll-back is carried out at the cycle i+1 and the vector \vec{pi}ᵢ₋₁⊕\vec{so}ᵢ₋₁ is supplied to the combinatorial part, i.e. exactly the input vector already supplied two cycles beforehand.

From \vec{pi}₂ᵢ₋₁=\vec{pi}₂ᵢ=\vec{PI}ᵢ, it accordingly follows that b and b′ represent two identical (respectively different) over-sampled bits at each odd (respectively even) cycle: \vec{b}₂ᵢ₋₁=\vec{b}′₂ᵢ₋₁. Since a fault is detected on the odd cycle, the recovery phase, which begins one cycle later, will then read two different inputs (i.e. not the same over-sampled input) in b and b′, which is relevant in the mode with no redundancy, i.e. accelerated, implemented during the recovery phase. The behavior of the input buffer memories is illustrated in tables 1 and 2.

The recovery phase (mode with no temporal redundancy) interferes with the data stream of the vectors \vec{co} of the circuit with respect to the normal mode of operation (mode with redundancy of order 2). In order to mask this effect on the primary outputs, an output buffer memory is inserted before each primary output po (each output po corresponds to a component of the vector \vec{po}). Such an output buffer memory 60 is shown in one embodiment in FIG. 12. The signal co comes from the combinatorial part 11. The buffer memory 60 is adapted to be tolerant to a SET occurring in the buffer memory 60 or on its outputs. For this purpose, the primary outputs are tripled: poA, poB and poC are the primary outputs of the transformed circuit corresponding to the primary output po of the initial circuit.

The output buffer memories guarantee that at least two of the tripled outputs are correct at each even cycle. The surrounding circuit can thus read these outputs on the even cycle and carry out a vote on these outputs read so as to mask any SET. In different embodiments, other output blocks (for example, ignoring the faults at the outputs) or other interface specifications could be used.

The behavior of the output buffer memories during the recovery phase is also illustrated in table 2.

Tables 1 and 2 hereinbelow illustrate a case a fault is detected at the cycle i.

In tables 1 and 2, a vector \vec{v} corrupted by any given number of corrupted bits is denoted †\vec{v}.

In grayed tables 1a and 2b are indicated the values of the signals which would have been obtained in the absence of a fault detection.

TABLE 1

| clk | \vec{pi} | \vec{b} | \vec{b′} | \vec{ci} | \vec{d} | \vec{d′} | \vec{r} | \vec{r′} | fail | save | rollBack |
|---|---|---|---|---|---|---|---|---|---|---|---|
| i−3 | \vec{pi}ᵢ₋₃ | \vec{pi}ᵢ₋₄ | \vec{pi}ᵢ₋₅ | \vec{pi}_{i-3 ⊕} \vec{si}ᵢ₋₅ | \vec{si}ᵢ₋₄ | \vec{si}ᵢ₋₅ | \vec{si}ᵢ₋₅ | \vec{si}ᵢ₋₇ | ? | 1 | 0 |
| i−2 | \vec{pi}ᵢ₋₂ | \vec{pi}ᵢ₋₃ | \vec{pi}ᵢ₋₄ | \vec{pi}_{i-2 ⊕} \vec{si}ᵢ₋₄ | \vec{si}ᵢ₋₃ | \vec{si}ᵢ₋₄ | \vec{si}ᵢ₋₃ | \vec{si}ᵢ₋₅ | 0 | 0 | 0 |
| i−1 | \vec{pi}ᵢ₋₁ | \vec{pi}ᵢ₋₂ | \vec{pi}ᵢ₋₃ | \vec{pi}_{i-1 ⊕} \vec{si}ᵢ₋₃ | \vec{si}ᵢ₋₂ | \vec{si}ᵢ₋₃ | \vec{si}ᵢ₋₃ | \vec{si}ᵢ₋₅ | ? | 1 | 0 |
| i | \vec{pi}ᵢ | \vec{pi}ᵢ₋₁ | \vec{pi}ᵢ₋₂ | \vec{pi} _{⊕} †\vec{si}ᵢ₋₂ | ‡\vec{si}ᵢ₋₁ | †\vec{si}ᵢ₋₂ | ‡\vec{si}ᵢ₋₁ | \vec{si}ᵢ₋₃ | 1 | 0 | 0 |
| i+1 | \vec{pi}ᵢ₊₁ | \vec{pi}ᵢ | \vec{pi}ᵢ₋₁ | \vec{pi}_{i-1 ⊕} \vec{si}ᵢ₋₃ | †\vec{si}ᵢ | ‡\vec{si}ᵢ₋₁ | ‡\vec{si}ᵢ₋₁ | \vec{si}ᵢ₋₃ | ? | 1 | 1 |
| i+2 | \vec{pi}ᵢ₊₂ | \vec{pi}ᵢ₊₁ | \vec{pi}ᵢ | \vec{pi}_{i+1 ⊕} \vec{si}ᵢ₋₁ | \vec{si}ᵢ₋₁ | †\vec{si}ᵢ | \vec{si}ᵢ₋₁ | ‡\vec{si}ᵢ₋₁ | ? | 0 | 1 |
| i+3 | \vec{pi}ᵢ₊₃ | \vec{pi}ᵢ₊₂ | \vec{pi}ᵢ₊₁ | \vec{pi}_{i+3 ⊕} \vec{si}ᵢ₊₁ | \vec{si}ᵢ₊₁ | \vec{si}ᵢ₋₁ | \vec{si}ᵢ₋₁ | ‡\vec{si}ᵢ₋₁ | ? | 0 | 1 |
| i+4 | \vec{pi}ᵢ₊₄ | \vec{pi}ᵢ₊₃ | \vec{pi}ᵢ₊₂ | \vec{pi}_{i+4 ⊕} \vec{si}ᵢ₊₃ | \vec{si}ᵢ₊₃ | \vec{si}ᵢ₊₁ | \vec{si}ᵢ₋₁ | ‡\vec{si}ᵢ₋₁ | ? | 0 | 1 |
| i+5 | \vec{pi}ᵢ₊₅ | \vec{pi}ᵢ₊₄ | \vec{pi}ᵢ₊₃ | \vec{pi}_{i+5 ⊕} \vec{si}ᵢ₊₃ | \vec{si}ᵢ₊₄ | \vec{si}ᵢ₊₃ | \vec{si}ᵢ₋₁ | ‡\vec{si}ᵢ₋₁ | ? | 1 | 0 |
| i+6 | \vec{pi}ᵢ₊₆ | \vec{pi}ᵢ₊₅ | \vec{pi}ᵢ₊₄ | \vec{pi}_{i+6 ⊕} \vec{si}ᵢ₊₄ | \vec{si}ᵢ₊₅ | \vec{si}ᵢ₊₄ | \vec{si}ᵢ₊₅ | \vec{si}ᵢ₋₁ | 0 | 0 | 0 |
| i+7 | \vec{pi}ᵢ₊₇ | \vec{pi}ᵢ₊₆ | \vec{pi}ᵢ₊₅ | \vec{pi}_{i+7 ⊕} \vec{si}ᵢ₊₅ | \vec{si}ᵢ₊₆ | \vec{si}ᵢ₊₅ | \vec{si}ᵢ₊₅ | \vec{si}ᵢ₋₁ | ? | 1 | 0 |
| i+8 | \vec{pi}ᵢ₊₈ | \vec{pi}ᵢ₊₇ | \vec{pi}ᵢ₊₆ | \vec{pi}_{i+8 ⊕} \vec{si}ᵢ₊₆ | \vec{si}ᵢ₊₇ | \vec{si}ᵢ₊₆ | \vec{si}ᵢ₊₇ | \vec{si}ᵢ₊₅ | 0 | 0 | 0 |

TABLE 1a

| clk | \vec{ci} | \vec{d} | \vec{d′} | \vec{r} | \vec{r′} |
|---|---|---|---|---|---|
| i−3 | \vec{pi}_{i-3 ⊕} \vec{si}ᵢ₋₅ | \vec{si}ᵢ₋₄ | \vec{si}ᵢ₋₅ | \vec{si}ᵢ₋₅ | \vec{si}ᵢ₋₇ |
| i−2 | \vec{pi}_{i-2 ⊕} \vec{si}ᵢ₋₄ | \vec{si}ᵢ₋₃ | \vec{si}ᵢ₋₄ | \vec{si}ᵢ₋₃ | \vec{si}ᵢ₋₅ |
| i−1 | \vec{pi}ᵢ₋₁ _{⊕} \vec{si}ᵢ₋₃ | \vec{si}ᵢ₋₂ | \vec{si}ᵢ₋₃ | \vec{si}ᵢ₋₃ | \vec{si}ᵢ₋₅ |
| i | \vec{pi}_{i ⊕} \vec{si}ᵢ₋₂ | \vec{si}ᵢ₋₁ | \vec{si}ᵢ₋₂ | \vec{si}ᵢ₋₁ | \vec{si}ᵢ₋₃ |
| i+1 | \vec{pi}ᵢ₊₁ _{⊕} \vec{si}ᵢ₋₁ | \vec{si}ᵢ | \vec{si}ᵢ₋₁ | \vec{si}ᵢ₋₁ | \vec{si}ᵢ₋₃ |
| i+2 | \vec{pi}ᵢ₊₂ _{⊕} \vec{si}ᵢ | \vec{si}ᵢ₊₁ | \vec{si}ᵢ | \vec{si}ᵢ₊₁ | \vec{si}ᵢ₋₁ |
| i+3 | \vec{pi}ᵢ₊₃ _{⊕} \vec{si}ᵢ₊₁ | \vec{si}ᵢ₊₂ | \vec{si}ᵢ₊₁ | \vec{si}ᵢ₊₁ | \vec{si}ᵢ₋₁ |
| i+4 | \vec{pi}ᵢ₊₄ _{⊕} \vec{si}ᵢ₊₂ | \vec{si}ᵢ₊₃ | \vec{si}ᵢ₊₂ | \vec{si}ᵢ₊₃ | \vec{si}ᵢ₊₁ |
| i+5 | \vec{pi}ᵢ₊₅ _{⊕} \vec{si}ᵢ₊₃ | \vec{si}ᵢ₊₄ | \vec{si}ᵢ₊₃ | \vec{si}ᵢ₊₃ | \vec{si}ᵢ₊₁ |
| i+6 | \vec{pi}ᵢ₊₆ _{⊕} \vec{si}ᵢ₊₄ | \vec{si}ᵢ₊₅ | \vec{si}ᵢ₊₄ | \vec{si}ᵢ₊₅ | \vec{si}ᵢ₊₃ |
| i+7 | \vec{pi}ᵢ₊₇ _{⊕} \vec{si}ᵢ₊₅ | \vec{si}ᵢ₊₆ | \vec{si}ᵢ₊₅ | \vec{si}ᵢ₊₅ | \vec{si}ᵢ₊₃ |
| i+8 | \vec{pi}ᵢ₊₈ _{⊕} \vec{si}ᵢ₊₆ | \vec{si}ᵢ₊₇ | \vec{si}ᵢ₊₆ | \vec{si}ᵢ₊₇ | \vec{si}ᵢ₊₅ |

The indicators † and ‡ correspond to two exclusive cases of faults (which cannot occur at the same time).

TABLE 2

| clk | \vec{pi} | \vec{ci} | \vec{o} | \vec{o′} | \vec{o″} | \vec{po}A/B/C | fail | save | rollBack | rB | subst |
|---|---|---|---|---|---|---|---|---|---|---|---|
| i−3 | \vec{pi}ᵢ₋₃ | \vec{pi}_{i-3 ⊕} \vec{si}ᵢ₋₅ | \vec{co}ᵢ₋₄ | \vec{co}ᵢ₋₅ | \vec{co}ᵢ₋₆ | \vec{co}ᵢ₋₅ | ? | 1 | 0 | 0 | 0 |
| i−2 | \vec{pi}ᵢ₋₂ | \vec{pi}_{i-2 ⊕} \vec{si}ᵢ₋₄ | \vec{co}ᵢ₋₃ | \vec{co}ᵢ₋₄ | \vec{co}ᵢ₋₅ | ignore | 0 | 0 | 0 | 0 | 0 |
| i−1 | \vec{pi}ᵢ₋₁ | \vec{pi}_{i-1 ⊕} \vec{si}ᵢ₋₃ | \vec{co}ᵢ₋₂ | \vec{co}ᵢ₋₃ | \vec{co}ᵢ₋₄ | \vec{co}ᵢ₋₃ | ? | 1 | 0 | 0 | 0 |
| i | \vec{pi}ᵢ | \vec{pi} _{⊕} †\vec{si}ᵢ₋₂ | ‡\vec{co}ᵢ₋₁ | ‡\vec{co}ᵢ₋₂ | \vec{co}ᵢ₋₃ | ignore | 1 | 0 | 0 | 0 | 0 |
| i+1 | \vec{pi}ᵢ₊₁ | \vec{pi}_{i-1 ⊕} \vec{si}ᵢ₋₃ | \vec{co}ᵢ | ‡\vec{co}ᵢ₋₁ | ‡\vec{co}ᵢ₋₂ | \vec{co}ᵢ₋₁ (←) | ? | 1 | 1 | 1 | 1 |
| i+2 | \vec{pi}ᵢ₊₂ | \vec{pi}_{i+1 ⊕} \vec{si}ᵢ₋₁ | \vec{co}ᵢ₋₁ | \vec{co}ᵢ | ‡\vec{co}ᵢ₋₁ | Ignore | ? | 0 | 1 | 1 | 1 |
| i+3 | \vec{pi}ᵢ₊₃ | \vec{pi}_{i+3 ⊕} \vec{si}ᵢ₊₁ | \vec{co}ᵢ₊₁ | \vec{co}ᵢ₋₁ | †\vec{co}ᵢ | \vec{co}ᵢ₊₁ (←) | ? | 0 | 1 | 0 | 1 |
| i+4 | \vec{pi}ᵢ₊₄ | \vec{pi}_{i+4 ⊕} \vec{si}ᵢ₊₃ | \vec{co}ᵢ₊₃ | \vec{co}ᵢ₊₁ | \vec{co}ᵢ₋₁ | ignore | ? | 0 | 1 | 0 | 0 |
| i+5 | \vec{pi}ᵢ₊₅ | \vec{pi}_{i+5 ⊕} \vec{si}ᵢ₊₃ | \vec{co}ᵢ₊₄ | \vec{co}ᵢ₊₃ | \vec{co}ᵢ₊₁ | \vec{co}ᵢ₊₃ | ? | 1 | 0 | 0 | 0 |
| i+6 | \vec{pi}ᵢ₊₆ | \vec{pi}_{i+6 ⊕} \vec{si}ᵢ₊₄ | \vec{co}ᵢ₊₅ | \vec{co}ᵢ₊₄ | \vec{co}ᵢ₊₃ | ignore | 0 | 0 | 0 | 0 | 0 |
| i+7 | \vec{pi}ᵢ₊₇ | \vec{pi}_{i+7 ⊕} \vec{si}ᵢ₊₅ | \vec{co}ᵢ₊₆ | \vec{co}ᵢ₊₅ | \vec{co}ᵢ₊₄ | \vec{co}ᵢ₊₅ | ? | 1 | 0 | 0 | 0 |
| i+8 | \vec{pi}ᵢ₊₈ | \vec{pi}_{i+8 ⊕} \vec{si}ᵢ₊₆ | \vec{co}ᵢ₊₇ | \vec{co}ᵢ₊₆ | \vec{co}ᵢ₊₅ | ignore | 0 | 0 | 0 | 0 | 0 |

| clk | \vec{o} | \vec{o′} | \vec{o″} | \vec{po}A/B/C |
|---|---|---|---|---|
| i−3 | \vec{co}ᵢ₋₄ | \vec{co}ᵢ₋₅ | \vec{co}ᵢ₋₆ | \vec{co}ᵢ₋₅ = \vec{co}ᵢ₋₆ |
| i−2 | \vec{co}ᵢ₋₃ | \vec{co}ᵢ₋₄ | \vec{co}ᵢ₋₅ | ignore |
| i−1 | \vec{co}ᵢ₋₂ | \vec{co}ᵢ₋₃ | \vec{co}ᵢ₋₄ | \vec{co}ᵢ₋₃ = \vec{co}ᵢ₋₄ |
| i | \vec{co}ᵢ₋₁ | \vec{co}ᵢ₋₂ | \vec{co}ᵢ₋₃ | ignore |
| i+1 | \vec{co}ᵢ | \vec{co}ᵢ₋₁ | \vec{co}ᵢ₋₂ | \vec{co}ᵢ₋₁ = \vec{co}ᵢ₋₂ |
| i+2 | \vec{co}ᵢ₊₁ | \vec{co}ᵢ | \vec{co}ᵢ₋₁ | ignore |
| i+3 | \vec{co}ᵢ₊₂ | \vec{co}ᵢ₊₁ | \vec{co}ᵢ | \vec{co}ᵢ₊₁ = \vec{co}ᵢ |
| i+4 | \vec{co}ᵢ₊₃ | \vec{co}ᵢ₊₂ | \vec{co}ᵢ₊₁ | ignore |
| i+5 | \vec{co}ᵢ₊₄ | \vec{co}ᵢ₊₃ | \vec{co}ᵢ₊₂ | \vec{co}ᵢ₊₃ = \vec{co}ᵢ₊₂ |
| i+6 | \vec{co}ᵢ₊₅ | \vec{co}ᵢ₊₄ | \vec{co}ᵢ₊₃ | ignore |
| i+7 | \vec{co}ᵢ₊₆ | \vec{co}ᵢ₊₅ | \vec{co}ᵢ₊₄ | \vec{co}ᵢ₊₅ = \vec{co}ᵢ₊₄ |
| i+8 | \vec{co}ᵢ₊₇ | \vec{co}ᵢ₊₆ | \vec{co}ᵢ₊₅ | ignore |

The indicators † and ‡ correspond to two cases of faults (which cannot occur at the same time). (←) indicates a substitution of data carried out by the multiplexers muxAs, muxAs, muxCs, muxDs of an output buffer memory 60.

The control signals save, rollBack, rB and subst are generated by the control block 15 in order to implement the functionality of the transformed circuit during the normal mode of operation and the recovery phase. The input of the control block 15 is the fault detection signal fail (different separate fail signals come from the various memory blocks 14 and from the output buffer memories 60)

FIG. 13 shows the finite state machine (FSM) of the control block 15 in one embodiment of the invention. The notation a?b here indicates that the change of state is carried out if the condition a=b is true, for example if a signal fail is detected equal to 0 in the case fail ?0. The sign =indicates the action of assigning a value to a signal, for example if a fail signal is detected equal to 1, the value 1 is assigned to the signals rB, save, rollBack and subst during the next cycle. In this figure, all the control signals emitted by the control block 15 and not mentioned during a change of state are set to 0. The states norm1 and norm2 correspond to the normal mode of operation, which gives rise to the alternating setting to 1 of the signal save. When a fault is detected (receipt of a fail signal equal to 1), the FSM goes into recovery phase for 4 cycles corresponding to the successive states “error”, “recov1”, “recov2”, “recov3”.

The control block 15 itself is not protected against the SETs by temporal redundancy. In one embodiment, it is protected by TMR. The values taken by the control signals in the various states are indicated in tables 1 and 2.

Normal Mode of Operation

For as long as no fault is detected on the odd cycles, the mode of operation of the circuit is the normal mode of operation (mode with redundancy of order 2).

During this mode, the value of the control signal rollback is always set at 0 by the control block 15.

The signal save is set at 1 at each even cycle: save₂ᵢ₋₁=0 and save₂ᵢ=1.

Since save is the signal (“enable” signal) for triggering the storing by the cells r and r′, a delay of four cycles is inserted between si and r′ in the normal mode of operation.

The internal behavior of each memory block 40 in the normal mode of operation is then described by the following equations (7):

rollBackᵢ=0

\vec{si}ᵢ=\vec{d}ᵢ₊₁=\vec{d′}ᵢ₊₂=\vec{so}ᵢ₊₂

\vec{si}₂ᵢ=\vec{r}₂ᵢ₊₁=\vec{r}₂ᵢ₊₂=\vec{r′}₂ᵢ₊₂=\vec{r′}₂ᵢ₊₃=\vec{r′}₂ᵢ₊₄

save₂ᵢ₋₁=0,save₂ᵢ=1.

As previously seen, the comparison of d and d′ is only relevant during the odd cycles, the cells d and d′ then comprising, except in the case of a fault, redundant data values.

The transformed circuit verifies the same equations (1) as the original circuit:

\vec{co}ᵢ=φ(\vec{ci}ᵢ) \vec{ci}ᵢ=\vec{pi}ᵢ⊕\vec{so}ᵢ \vec{co}ᵢ=\vec{po}ᵢ⊕\vec{si}ᵢ (8)

Equations (7) and (8) and from the equality \vec{pi}₂ᵢ₋₁=\vec{pi}₂ᵢ=\vec{PI}ᵢ derive two properties of the normal mode of operation.

Property 1: first of all, the output bit stream co from the combinatorial part 11 after the transformation of the circuit is a double over-sampling of the bit stream \vec{CO} of the original circuit. Formally: \vec{co}_{2i<1}=\vec{co}₂ᵢ=\vec{CO}ᵢ for any natural integer i.

Property 2: furthermore, at each odd cycle, the outputs of the cells d and d′ are equal: \vec{d}₂ᵢ₋₁=\vec{d′}₂ᵢ₋₁ for any natural integer i.

The detection error corresponds to a determination of a violation of this property 2 by the comparator EQ.

If, during an odd cycle, the contents of the cells d and d′ differ, an error is thus detected and the signal fail is set to 1 (fail₂ⱼ₋₁=1). The circuit must then carry out a roll-back to the correct state recorded in r′ and re-calculate the preceding step. The roll-back is carried out by propagating the content of the cell r′ to \vec{so}.

It follows from the equations (17) that \vec{r′}₂ⱼ₋₁=\vec{r′}₂ⱼ=\vec{si}₂ⱼ₋₄, which means that, at the moment of a fault detection (and on the clock cycle that follows), the content of the recovery memory cell r′ is equal to the value that the input signal had 3 cycles beforehand.

Recovery Phase

When a fault is detected, the circuit carries out a roll-back during the cycle following the fault detection, then carries out three consecutive cycles during which the temporal redundancy of order 2 in the memory blocks is replaced by a mode with no temporal redundancy and by the application by the control block 15 of the sequence of control signals save, rollBack, subst and rB shown in FIG. 13 between the state “error” and until it returns to the state “norm2”.

Table 1 contains the values of the bit-vectors in the transformed circuit cycle by cycle when a fault is detected at the cycle i. The behavior of the circuit in normal mode (i.e. in the absence of a fault) is indicated in table 1 a.

In normal mode, the vector \vec{ci} at the cycle i is such that \vec{ci}ᵢ=\vec{pi}ᵢ⊕\vec{so}ᵢ=\vec{pi}ᵢ⊕\vec{si}ᵢ₋₂. The principle of roll-back is that the memory blocks 40 re-inject the last saved state into the cells r′ (vector \vec{si}), whereas the input buffer memories re-inject the corresponding primary inputs (vector \vec{pi}) that were stored in them.

At the cycle (1+1) that follows the error detection in the cycle i, the recovery phase commences and the correct state stored in the cell r′ is propagated through the signal so.

As a consequence, \vec{so}ᵢ₊₁=\vec{r′}ᵢ₊₁=\vec{si}ᵢ₋₃ instead of \vec{si}ᵢ₋₁, expected in the normal mode of operation. Consequently, the second component of \vec{ci}ᵢ₊₁ is \vec{si}ᵢ₋₁. The primary input vector is also replaced by the vector stored in the input buffer memory: thus, at the cycle 1+1, \vec{pi}ᵢ₊₁ is replaced by \vec{pi}ᵢ₋₁. It is recalled that, during the recovery phase, the circuit operates with the data rate of the original circuit, which is twice as fast as in the normal mode. In particular, during the cycles i+2, i+3 and i+4, the content of the memory cell d is propagated directly through the outputs \vec{so} of each memory block 40, by short-circuiting the memory cells d′. This is implemented by fixing the control signal rollBack to 1, while keeping the signal save at 0 which controls the multiplexers muxA and muxB in a suitable manner. This is of no consequence since the fault model SET(1,K) guarantees that no additional fault occurs during the K cycles after a SET.

At the cycle i+2, the second component of \vec{ci}ᵢ₊₂ is \vec{si}ᵢ₋₁ (\vec{si}ᵢ₋₂, which is identical to \vec{si}ᵢ₋₁, has been skipped). Similarly, the primary input vector is replaced by \vec{pi}ᵢ₊₁ since, in the input buffer memories,\vec{b′}ᵢ₊₂=\vec{pi}ᵢ and \vec{pi}ᵢ₊₁=\vec{pi}ᵢ. It follows from this that \vec{ci}ᵢ₊₁=\vec{pi}ᵢ₋₁⊕\vec{si}ᵢ₋₁ and \vec{ci}ᵢ₊₂=\vec{pi}ᵢ₊₁⊕\vec{si}ᵢ₋₁.

All the corrupted signals have disappeared from the circuit in the 6 cycles following the detection error. The whole circuit returns into a correct state after 8 cycles after the detection at the most.

In other embodiments of a transformed circuit, where the aspects of double dynamic temporal redundancy and of recording with roll-back are combined, a single cell r′ is used instead of the cells r and r′. The control signal save is set to 1 every other cycle. The detection error and the recovery functionality remain at the expense of a reduction in the tolerance to faults. A SET on the wire \vec{si}, for example caused by a SET in the combinatory logic, may in this case simultaneously corrupt r′ and d if save=1. The error is detected at the following cycle and the recovery takes place by using the corrupted information of the cell r′.

In reality, the cell r plays a role of isolation which prevents the recovery bit from being re-written until this information has been verified by the comparator EQ.

In various embodiments, the architectures of the output buffer memories are simplified, the main function being maintained: implement a delay on the signal co in the normal mode of operation with a mechanism for propagating co to po during the recovery phase.

A transformed circuit according to this embodiment of the invention carries out the propagation of the signal through the combinatorial part of the circuit twice prior to the comparison, with a roll-back and a re-execution when an error is detected. According to a fault model SET(1, K), no error occurring in the K cycles after the last fault occurred, the level 2 redundancy mechanism is then eliminated and the circuit is accelerated by a factor of two. It returns into its correct state (i.e. the state of the circuit if no error had occurred) after 8 cycles after detection or 10 cycles after the occurrence of the SET.

A transformed circuit according to this embodiment may also operate in accelerated mode (n=1) when the tolerance to faults is not necessary.

FIG. 14 shows steps of a method for automated manufacturing of an electronic circuit tolerant to faults by temporal redundancy, which is implemented in one embodiment of the invention.

These steps, for example implemented by a tool for automated synthesis of electronic circuits, are:
step 80 for receiving a design of the original circuit at the logic level;
step 90 for choosing the transformation required and the type of dynamic redundancy (level of redundancy, modes of operation and fault tolerance properties);
step 100 for transformation of the memory blocks of the original circuit into memory blocks for the implementation of the chosen dynamic redundancy, comprising:
i/ step 101: generation of the memory block;
ii/ step 102: replacement of each memory cell of the original circuit by the memory block generated in the design of the circuit;
iii/ step 103: generation of the control block (and for the double dynamic redundancy with roll-back, input and output buffer memories);
iv/ step 104: insertion of the control block (and in the case of double dynamic redundancy with roll-back, input and output buffer memories) into the design of the circuit and interconnections between the control block and the transformed memory blocks of the circuit (and, in the case of the double dynamic redundancy with roll-back, with the input and output buffer memories).

FIG. 15 describes various steps of the design flow for integrated circuits corresponding to various levels of abstraction in one embodiment of the invention:
step 201: synthesis at the system level, on the basis of specifications of the circuit, comprising the allocation or the division between software and hardware, one of the results of which is a high-level and behavioral description of the circuit;
step 202: synthesis of the high-level circuit on the basis of this description (transformation, planning, selection of modules), one of the results of which is an architectural description, at the ‘register transfer level’ or RTL: this modeling amounts to describing the implementation in the form of sequential elements (registers, flip-flops) and of logical combinations between the various inputs/outputs of the sequential elements and of the primary inputs/outputs of the circuit:
step 203: logical synthesis of the circuit as a function of this RTL description, which transforms the RTL description of the circuit into a logic-level description, in terms of logic gates (Gate netlist): this step 203 comprising the following successive sub-steps:
   functions from RTL to Boolean;
   independent optimizations of the technology;
transformation 100 of the circuit for the dynamic redundancy according to the invention;
mapping technology;
optimizations dependent on the technology;
step 204: physical mask synthesis for the circuit on the basis of the logical description. For VLSI circuits, this synthesis comprises the description of the circuit at the level of the transistors (placement, routing, cycle distribution) and delivers a description of the circuit at the level of the mask. For FPGA circuits, this synthesis comprises the translation, the topography (placement, routing) and delivers a programming file.

The transformation 100 provides the fault tolerance properties for the circuit. In the embodiment described, it is implemented after the optimizations independent of the technology (the properties will therefore be preserved by the later steps) and prior to the separation of the flow into VLIF technology or FPGA technology, which allows it to be applied conjointly to both technologies.

1. A method for manufacturing an electronic circuit adapted to detect or mask faults by temporal redundancy, the method comprising:
inserting a memory block into the electronic circuit, wherein the electronic circuit comprises a delay chain comprising N memory cells in series, N≧2, and a selection block (voter/detector) which, in one mode of operation corresponding to a temporal redundancy of order n1, involving n1 re-executions, n1∈[1,N], compares the current content of the n1 memory cells storing n1 redundant input data values successively supplied to the memory block, and wherein:
if n1>2, select a majority content of the n1 memory cells as output data of the memory cell function and furthermore optionally delivers a fault signal if the contents of two memory cells differ;
if n1=2, deliver the content of one of the two memory cells containing the current redundant data value as output data of the memory cell function and furthermore delivers a fault signal if the contents of these two memory cells differ;
if n1=1, deliver the content of the given memory cell as output data of the memory cell function;
wherein a control block of the circuit is adapted to generate signals for controlling the memory blocks is furthermore inserted, and in that the memory block inserted is adapted to switch, as a function of a switching control signal received from the control block, between said mode of operation corresponding to a temporal redundancy of order n1 and another mode of operation corresponding to a temporal redundancy of order n2∈[1,N] according to which the circuit performed n2 re-executions, n2≠n1, in which the selection block compares the current content of n2 cells determined from amongst the N memory cells storing n2 redundant input data values successively supplied to the memory block, and wherein:
if n2>2, select the majority content of said n2 memory cells as output data of the memory cell function;
if n2=2, deliver the content of one of the two memory cells as output data of the memory cell function and deliver a fault signal if the contents of the two memory cells differ;
if n2=1, deliver the content of the given memory cell as output data of the memory cell function.

2. The method of claim 1, according to which the inserted memory block furthermore comprises, when N>2, an additional delay block disposed at the output of the delay chain and comprising at least
$$E [ \frac{N - 1}{2} ]$$
memory cells,
in a mode of operation corresponding to a temporal redundancy of order n, n>2, every n cycles, the selection block selects as output data of the memory cell function, the majority content of the n memory cells of the delay chain, and each i^{th} cycle following said n cycles, with 1<i<n, selects as output data of the memory cell function the majority content of a set of last cells of the delay chain and of cells of the additional delay block, said cells of the set storing redundant input data values having been successively supplied to the memory block.

3. The method of claim 1, according to which N=3, n1=1, n1=2, or n1=3 and n2, n2≠n1, takes a value equal to 1, 2 or 3 depending on the switching command.

4. The method of claim 1, according to which N=2, n=1 or 2 and n2=1 or 2, n2≠n1.

5. The method of claim 4, according to which the command for switching the mode of operation according to a temporal redundancy of order 2 to the mode of operation according to a temporal redundancy of order 1, and vice versa, is triggered when the control block has received a fault signal delivered by one of the memory blocks.

6. The method of claim 4, according to which the second cell of the delay chain stores, at each clock cycle of the circuit, the content stored at the preceding clock cycle in the first cell of the delay chain,
according to which the inserted memory block furthermore comprises a recording chain adapted, upon receiving a recording command signal from the control block, to store the input signal value of the memory block also supplied in parallel to the first cell of the delay chain, according to which, in a mode of operation according to a redundancy of order 2, the recording command signal is generated every other cycle in such a manner that, when redundant data values stored in the two memory cells of the delay chain are compared by the selection block, the last cell of the recording chain comprises in memory the data that was stored two cycles beforehand in each of the two memory cells of the delay chain.

7. The method of claim 6, according to which, following the receipt by the control block of a fault signal delivered by a memory block indicating that redundant data values stored in the two memory cells of the delay chain differ, the control block supplies a roll-back command to the memory block, following which the memory block delivers as output data of the memory cell function the current content of the last cell of the recording chain, said method thus allowing an error to be masked with only a double redundancy instead of a triple redundancy.

8. The method of claim 4, according to which an input block of the circuit receiving the current external data to be processed over-sampled twice is furthermore inserted at the input of the electronic circuit,
the input block, in the mode of operation according to a temporal redundancy of order 2, storing in memory the received current external data and furthermore simultaneously supplying said received current external data to the circuit, and the input block, in the mode of operation according to a temporal redundancy of order 1, supplying the circuit with successive non-redundant external data values previously stored by the input block in order to allow a third execution of this data by the circuit; and
according to which an output block of the circuit receiving the data delivered by the circuit is furthermore inserted at the output of the electronic circuit, said output block, in the mode of operation according to a temporal redundancy of order 2, storing the data delivered by the circuit and applying a given delay prior to delivering it, and the output block, in the mode of operation according to a temporal redundancy of order 1, delivering the data delivered by the circuit with no delay, duplicating data delivered by the circuit and delivering the duplicated data, the recovery of faults by the circuit thus being masked vis-à-vis the upstream of the circuit and the downstream of the circuit by said input and output blocks.

9. (canceled)

10. An electronic circuit adapted to detect or mask faults by temporal redundancy, comprising a set of memory blocks, each memory block of said set comprising a delay chain comprising N memory cells in series, N≧2, and a selection block which, in a mode of operation corresponding to a temporal redundancy of order n1, n1∈[1,N], compares the current content of n1 of said N memory cells storing n1 redundant input data values successively supplied to the memory block, and wherein:
if n1>2, selects a majority content of the n1 memory cells as output data of the memory cell function and, optionally, furthermore delivers a fault signal if the contents of two memory cells differ;
if n1=2, delivers the content of one of the two memory cells as output data of the memory cell function and furthermore delivers a fault signal if the contents of the two memory cells differ;
if n1=1, delivers the content of the given memory cell as output data of the memory cell function;
said electronic circuit being characterized in that it comprises a control block of the circuit adapted to generate control signals for said memory blocks, and in that each of said memory blocks is adapted to, depending on a switching control signal received from the control block, switch between said mode of operation corresponding to a temporal redundancy of order n1 and another mode of operation corresponding to a temporal redundancy of order n2∈[1,N], n2≠n1, in which the selection block compares the current content of n2 determined cells, from amongst said N memory cells, storing n2 redundant input data values successively supplied to the memory block, and:
if n2>2, selects the majority content of said n2 memory cells as output data of the memory cell function ;
if n2=2, delivers the content of one of the two memory cells as output data of the memory cell function and delivers a fault signal if the contents of the two memory cells differ;
if n2=1, delivers the content of the given memory cell as output data of the memory cell function.

11. The electronic circuit of claim 10, in which the memory block furthermore comprises, when N>2, an additional delay block disposed at the output of the delay chain and comprising at least
$$E [ \frac{N - 1}{2} ]$$
memory cells, in a mode of operation corresponding to a temporal redundancy of order n, n>2, every n cycles, the selection block selects as output data of the memory cell function the majority content of the n memory cells of the delay chain, and each i^{th} cycle following said n cycles, with 1≦i<n, selects as output data of the memory cell function the majority content of a set of last cells of the delay chain and of cells of the additional delay block, said cells of the set storing redundant input data values having been successively supplied to the memory block.

12. The electronic circuit of claim 10, in which N=3, n1=1, 2, or 3 and n2, n2≠n1, takes a value equal to 1, 2 or 3 as a function of the switching command.

13. The electronic circuit of claim 10, in which N=2, n1=1 or 2 and n2=1 or 2, n2≠n1.

14. The electronic circuit of claim 13, adapted to trigger, when the control block has received a fault signal delivered by one of the memory blocks, the command for switching the mode of operation according to a temporal redundancy of order 2 to the mode of operation according to a temporal redundancy of order 1, and vice versa.

15. The electronic circuit of claim 13, in which the second cell of the delay chain stores, at each clock cycle of the circuit, the content stored at the preceding clock cycle in the first cell of the delay chain, each of said memory blocks furthermore comprises a recording chain adapted, upon receipt of a recording command signal of the control block, to store the input signal value of the memory block also supplied in parallel to the first cell of the delay chain, in a mode of operation according to a redundancy of order 2, the recording command signal is generated every other cycle in such a manner that, when redundant data values stored in the two memory cells of the delay chain are compared by the selection block, the last cell of the recording chain comprises in memory the data that was stored two cycles beforehand in each of the two memory cells of the delay chain.

16. The electronic circuit of claim 15, in which, when a control block has received a fault signal delivered by a memory block indicating that redundant data values stored in the two memory cells of the delay chain differ, the control block supplies a roll-back command to the memory block, following which the memory block delivers as output data of the memory cell function the current content of the last cell of the recording chain, said electronic circuit thus allowing an error to be masked with only a double redundancy instead of a triple redundancy.

17. The electronic circuit of claim 13, comprising an input block of the circuit receiving the current external data to be processed over-sampled twice, the input block, in the mode of operation according to a temporal redundancy of order 2, storing in memory the received current external data and furthermore simultaneously supplying said received current external data to the circuit, and the input block, in the mode of operation according to a temporal redundancy of order 1, supplying the circuit with successive non-redundant external data previously stored by the input block in order to allow a third execution of this data by the circuit; and
said electronic circuit comprising at the output of the electronic circuit an output block of the circuit receiving the data delivered by the circuit, said output block, in the mode of operation according to a temporal redundancy of order 2, storing in memory the data delivered by the circuit and applying a given delay prior to delivering it, and the output block, in the mode of operation according to a temporal redundancy of order 1, delivering the data values delivered by the circuit with no delay, duplicating data values delivered by the circuit and delivering the duplicated data,
the recovery of faults by the circuit thus being masked vis-à-vis the upstream of the circuit and the downstream of the circuit by said input and output blocks.

18. A non-transitory computer accessible medium that includes computer-executable instructions stored thereon that are executable by a computing device to perform the method of claim 1.
